(19) United States
(12) Patent Application Publication
(10) Pub. No.: US 2019/0313527 A1
(43) Pub. Date: Oct. 10, 2019

(54) BOARDS WITH PLIABLE REGIONS

(71) Applicant: HEWLETT- PACKARD DEVELOPMENT COMPANY, LP., Spring, TX (US)

(72) Inventors: Roger A. Pearson, Fort Collins, CO (US); Adolfo A. Gomez, Fort Collins, CO (US)

(73) Assignee: HEWLETT- PACKARD DEVELOPMENT COMPANY, L.P., Spring, TX (US)

(21) Appl. No.: 16/340,193

(22) PCT Filed: Oct. 10, 2016
(86) PCT No.: PCT/US2016/056303

§ 371 Date: Apr. 8, 2019

(51) Int. Cl. H05K 1/02

(52) U.S. Cl. CPC H05K 1/0278; H05K 2201/09063; H05K 2201/10446; H05K 2201/10189; H05K 2201/09081

(57) ABSTRACT

Examples disclosed herein relate to a rigid board with a pliable region. An example system can include a board including a cut to form a beam region of pliability in the board. An example system may include a component to be mounted on the beam region. In an example, the cut can increase flexibility of the beam region relative to the board allowing movement of the component to a target alignment for the component.

### BACKGROUND

Electronic devices typically have one or more boards on which electronic components are mounted. The board may be inflexible or flexible. The rigidity of the board may depend, for example, on the substrate that forms the board.

### DESCRIPTION OF THE DRAWINGS

Certain exemplary embodiments are described in the following detailed description and in reference to the drawings, in which:

FIG. 1 is a block diagram of an example board with a pliable region along an axis;

FIG. 2 is a block diagram of an example board with a pliable region along an axis to reduce rotational tilting;

FIG. 3 is a block diagram of an example board with multiple pliable regions along an axis to reduce rotational tilting;

FIG. 4 is a block diagram of an example board, chassis, and a pliable region to aid a board with a component to insert into a chassis opening;

FIG. 5 is a block diagram of an example board and a pliable region to aid a component alignment on a board;

FIG. 6 is a block diagram of an example board, chassis, and pliable regions to aid in fixing the board to the chassis and inserting a connector of the board into a chassis opening;

FIG. 7 is a block diagram of an example board with pliable regions to interlock;

FIG. 8 is a block diagram of an example board with multiple pliable regions in proximity to each other to increase pliability of a target region;

FIG. 9 is a block diagram of an example board with pliable regions internal to the board; and

FIG. 10 is a process flow diagram of forming a rigid board with pliable regions.

### DETAILED DESCRIPTION

A board on which electronic components can be mounted can be inflexible, depending on the substrate used to make the board. Substrates that are more rigid can include insulators such as flame retardant-4 (FR-4) glass epoxy or other suitable insulating substances. Flexible substrates such as polyimide, or the use of screen-printing onto polyester, or the forming of flexible electronics with photolithographic technology can be expensive compared to the use of a board with a rigid substrate.

In general, electronics or electronic devices can vary in size, shape, configuration, layout, and other similar dimensions. The use of rigid boards, while cheaper that flexible alternatives, can present a spatial challenge in electronic devices. Further, multiple rigid boards rather than one in an electronic device can result in additional connectors and cables between the boards.

In some examples, components installed on a rigid board are stuck in a single arrangement. Indeed, mounting taller components, for instance, onto a rigid board may force a single alignment of components on one edge rather than, for example, a central alignment relative to smaller components.

In contrast, examples herein may beneficially employ a rigid or semi-rigid board. In the present disclosure, a board can be a printed circuit board (PCB), a printed card assembly (PCA), or any other similar board on which electronic components can be mounted. This board may include a rigid substrate. Rigid substrates are substrates characterized by relative inflexibility in three dimensions that also have the ability to hold their own shape when subjected to a force. In an example, the substrate can be rigid if the substrate has three dimensions where the largest value of the dimensions indicates a length and the substrate keeps its shape when held length-wise in a plane tangent to Earth's gravitational force without deforming. In an example, a substrate can be a rigid substrate if its flexural strength is greater than 345 megapascals (mPA) at 0.125 inches thickness board using that substrate in a crosswise or fill yarn direction. In an example, a substrate can be a rigid substrate if its flexural strength is greater than 415 mPA at 0.125 inches thickness using that substrate for a lengthwise or warp yarn direction.

As disclosed herein to increase pliability, a board can be cut to add mechanical compliancy to a region of the board. As used herein, the cut may be a physical shearing or machining into the board, and can also include slots manufactured into the board such that no separation of board regions through shearing occurs. The cut, when added to the board, can result in a pliable region. The cut or several cuts may be added around an area of interest in order to achieve compliancy in X, Y, or Z axis, or any combination of axis flexibility. For example, the board includes two larger dimensions that create a plane on which components can be placed, and the board includes a smaller dimension. Z is the smaller dimension perpendicular to the plane, and X and Y lie in the plane. Through the creation of pliable regions, components that are mounted onto the beam regions created can flex in a direction perpendicular to the direction of a cut. For example, if a cut is a length-wise cut in an X direction, the pliable region may gain flexibility in either a width-wise direction, such as a Y direction, or a depth-wise direction, such as a Z direction.

Based on the number, location, and shape of the cuts, the pliable regions can result in a beam region of the board with more flexibility than the remainder area of the board. The increase in flexibility can be due to parts of the beam region no longer being attached to the rest of the board allowing increased rotation, flexing, and bending, The amount of compliancy can also be modified by the geometry of the cut or length of the cuts. In another example, a combination of cuts in varied directions can result in a region that can flex in a variety of different directions. The increased pliability can also eliminate the cost of mounting screws and can simplify assembly of a board or assembly of the board to a chassis.

Through the use of pliable regions on the board, certain examples of the presently disclosed technique can allow larger components to align at the smaller component's center-line or vice versa. The use of pliable regions may avoid tooling up a different, custom connector with desired height, the cost of which may be prohibitive, or which may introduce signal integrity issues. In an example, the larger components can be placed on a pliable region that bends or flexes until the larger component aligns to the smaller component's center-line. In a particular example, the smaller component's center-line can be a middle of a component on a single face of the smaller component. Larger and smaller components where at least one component is mounted on a pliable region can allow the components to be aligned to a center-line of the board, where the center-line is formed by an unflexed region of the board. Additionally, the use of compliance regions can be used not only for aligning centers of components, but also for aligning tops or bottoms or any arbitrary part of components. In examples, the board may also make use of pliable regions to shift one component up or down to avoid some other feature in the product. In an example, the cuts allow flexing of the board that deforms or squeezes part of the board to allow installation of the board into a chassis.

In some examples, enabling a board to be installed into a chassis that otherwise has points of interference results in a designed chassis with features allowing the interference point to be removed until after the board is installed. These features add complexity and cost to the chassis, and may introduce electromagnetic interference (EMI) issues. Conversely, in some examples of the present disclosure, when the board may not fit into a chassis without deformation or flexing, a cut in the board can be added. Adding a cut can result in a beam region and allow flexing of this newly pliable region to deform the board to fit inside the chassis. In another example, pliable regions can reduce risk of damage during attempts to flex a rigid board during assembly, where these flexing attempts on a rigid board without pliable regions could break the board or weaken solder joints.

As electronics can vary in layout, an internal layout may be more densely filled by adding a cut to a board to allow a central part of the board to be non-coplanar with the rest of the board. The region that may not be co-planar can offset a Z height of one region of the board where additional clearance grants space for additional components. The increased density granted through selective flexing can lower the overall thickness of the design.

In an example, the board created can include a first electrical component and a second electrical component that generate heat, where the second component varies (is different) in size from the first component. In this example, a system could include a cooling element. In this example system, the second component could be located on a second beam region of the board separate from the beam region of the first component, the beam region and the second beam region to be independently flexed to align the first component and the second component for exposure to the cooling element. As used herein, the cooling unit could be a fan, a liquid based cooling device, a metal device for induction cooling, and other cooling devices for electrical components. As used herein, the exposure of components to the cooling unit could include adjusting the height of each component that had varied sizes such that each component could be flush against a linear cooling element, or cooling air channel passing along an edge or surface of the components.

While the figure drawings show a direction axis indicating an X axis, X axis, and Z axis, these directions are shown and used here for convenience of description and may not reflect an orientation of the device or its components. The presentation of axis and components can be used to identify location orientation relative to other disclosed components. In an example, the X axis and Y axis are in the plane of the board, when a Z axis is perpendicular to the board. As observed in the figures, when the board is held flat and viewed on edge in front of the viewer, the X axis is in the direction of left-right, and that Y axis is front-back.

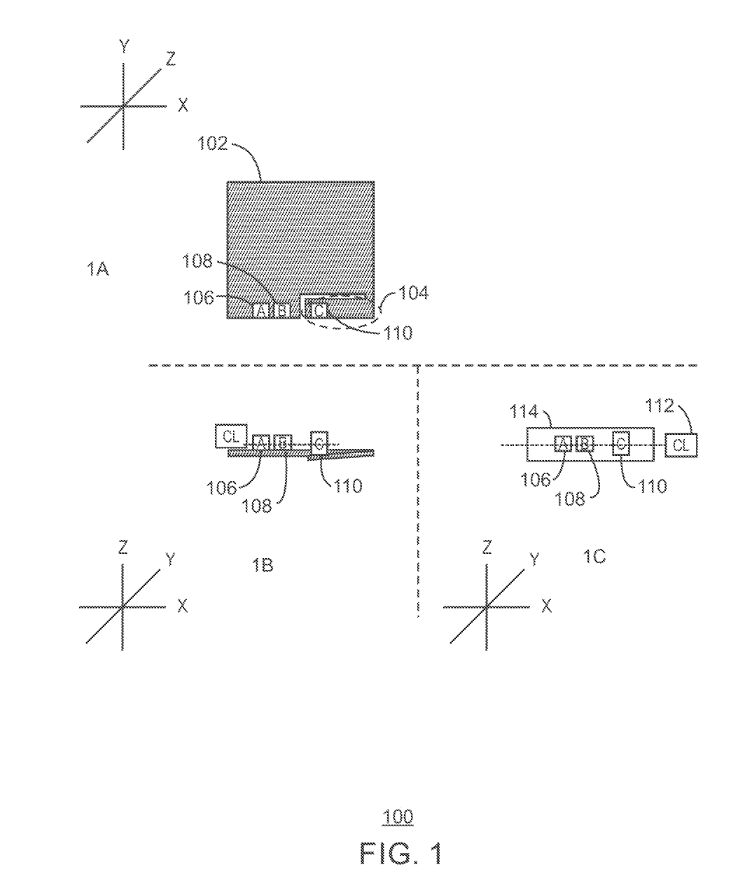

FIG. 1 is a block diagram of an example board with a pliable region along an axis 100. In order to show various aspects of the example board, FIG. 1 includes 1A, 1B, and 1C to show a board 102 from a top view, the board from a front view, and a view of an alignment of components as seen from an external view of a chassis, respectively. In the top-down view of FIG. 1A, the board 102, can be a printed circuit board, a printed board assembly, a bare board, or any other suitable rigid board on which to mount components. The board 102 has a cut in the lower right portion resulting in the formation of a beam region 104 that has increased flexibility, or pliability relative to the remainder of the board 102.

Component A 106, component B 108, and component C 110 can be mounted on the board 102. As used herein, the components can refer to connectors that act as channels between the board 102 and an external device. As used herein, the components can also refer to power switches and indicators. The components can also be connectors that communicate to other components mounted to the board 102. The components can be a processor, communication circuitry, a storage resource for digital information, or other resources mounted on a board 102. FIG. 1A shows component C 110 mounted on the beam region near the edge of the board 102.

In the front-view provided by FIG. 1B, component C 110 is shown as taller than component A 106 and component B 108. As component C 110 is located on a beam region 104, the beam region can flex downward, or move in a Z axis, to result in component C 110 reaching a target alignment such as a centerline alignment 112. As used herein, the target alignment can be any desired alignment for components. For example, a target alignment can be a centerline alignment 112 and can refer to a center-line formed by a smallest component, an average height, a designated measurement from a board 102, and other suitable alignments. In an example, the target alignment can also include aligning the tops or bottoms of components. Further, in place of a target alignment, the pliability can allow the movement of C to clear another component that could otherwise interfere with C or the beam in the region of C.

In a front-view external view of a chassis 114 of FIG. 1C, the components can be seen in their center-line alignment 112. As used herein, a chassis can be an external framework, covering, structure, or shell over the board. The chassis can be made of metal, wood, plastic, or can be other suitable materials used in encasing a board, in an example, while component C 110 is being moved in the Z axis, it may rotate slightly to correspond to the flexing of the beam region around a connection point to the board 102. To account for this, component C 110 may be attached to an opening in the chassis 114 that straightens out any slight skew resulting from rotation of the beam region 104. In another example, a component could be attached or additional features such as board edge guides could be used to straighten out any slight skew, Further, additional pliable regions could be added to the board to straighten a skew.

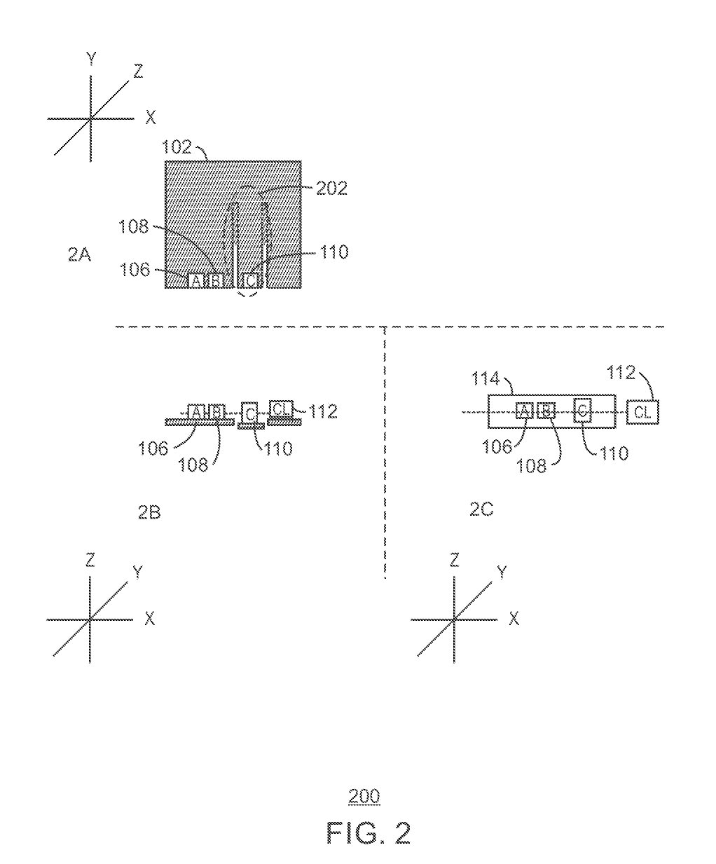

FIG. 2 is a block diagram of an example board with a pliable region along an axis to reduce rotational tilting 200. Like numbered items are as described with respect to FIG. 1. As used herein, rotational tilting can refer to the tilting of the component seen by the viewer when the cut is in an X axis rather than a Y axis direction. In order to show various aspects of the example board. FIG. 2 includes 2A, 2B, and 2C to show the board 102 from a top view, the board from a front view, and a view of an alignment of components as seen from an external view of a chassis, respectively. As described in FIG. 2, there may still be tilting of the component where when 110 is deflected down as shown, the top of component C can tilt out toward the viewer. The design of the compliant region can be adjusted to minimize the impact of the connector deflection, In some instances, a design such as is shown in FIG. 1 may have less impact on connector deflection. In some instances, a design such as is shown in FIG. 2 may have less impact on connector deflection.

As seen in FIG. 2A, particularly when compared to FIG. 1A, the cut on the board varies in direction. In FIG. 2A, the cuts can form a bounding beam region 202 by being placed on opposites sides of the component to be moved. As used herein, a beam region can be a bounding beam region 202 with the cuts placed on opposite sides of the component. Component C 110 can be moved while mounted in the bounding beam region 202 in a Z axis direction generally without rotational tilting. The rotational tilting reduction in FIG. 2 can be shown in comparison to FIGS. 1B and 2B where in FIG. 2B, the bounding beam region 202 allows component C 110 to reach center-line alignment 112 through a bend occurring in a different direction.

The bounding beam region 202 and the beam region 104 shown above can have varied flexibility or pliability by varying the length of the cut. The bounding beam region 202 can have a cut length calculated based on the Z axis displacement to move component C 110 to a target alignment. In FIGS. 2B and 2C, the target alignment is shown as a center-line alignment with the other components, although a target alignment may be symmetrical, asymmetrical, or another alignment set by design.

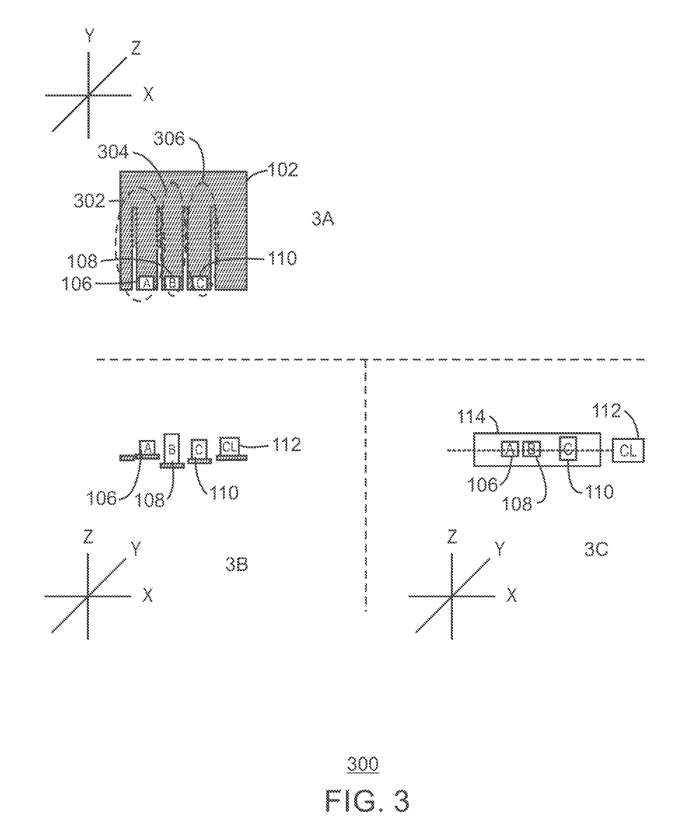

FIG. 3 is a block diagram of an example board with multiple pliable regions along an axis 300 to reduce rotational tilting. Like numbered items are as described with respect to FIG. 1. In order to show various aspects of the example board, FIG. 3 includes 3A, 3B, and 3C to show the board 102 from a top view, the board from a front view, and a view of an alignment of components as seen from an external view of a chassis, respectively.

In FIG. 3, component A 106, component B 108, and component C 110 have varying heights compared to one another. The inclusions of multiple cuts creates multiple bounding beam regions including a bounding beam region A 302 for mounting component A 106. a bounding beam region B 304 for mounting component B 108, and a bounding beam region C 306 for mounting component C 110. As seen in the top-side view of FIG. 3A, the cuts to create the multiple bounding beam regions can be common to multiple regions to reduce the number of cuts used for creating multiple pliable regions. The creation of multiple bounding beam regions allows each bounding beam region to articulate separately for each component to vary displacement along a Z axis to a differing degree. The degree of displacement can vary in order for each component to reach a target alignment. In FIG. 3B, the front-view shows component A 106, component B 108, and component C 110 each at varied heights to reach a center-line alignment. The cuts used to create the bounding regions can be determined by the amount of displacement to be used by the component mounted on the bounding beam region of that cut. When a cut is part of creating two or more bounding beam regions, the cut length can be determined by the greatest displacement of an adjacent bounding beam region created by the cut. The cuts on either side of a component can be the same length to prevent one side being more flexible than the other resulting in a component rotating as it is displaced. In an example, there may be two slots the same length on either side of “A”, two different slots the same length on either side of “B”, and two different slots the same length on either side of “C” (a total of 6 slots), where the slots for any one component are the same length, but may differ for each component, depending on the desired displacement.

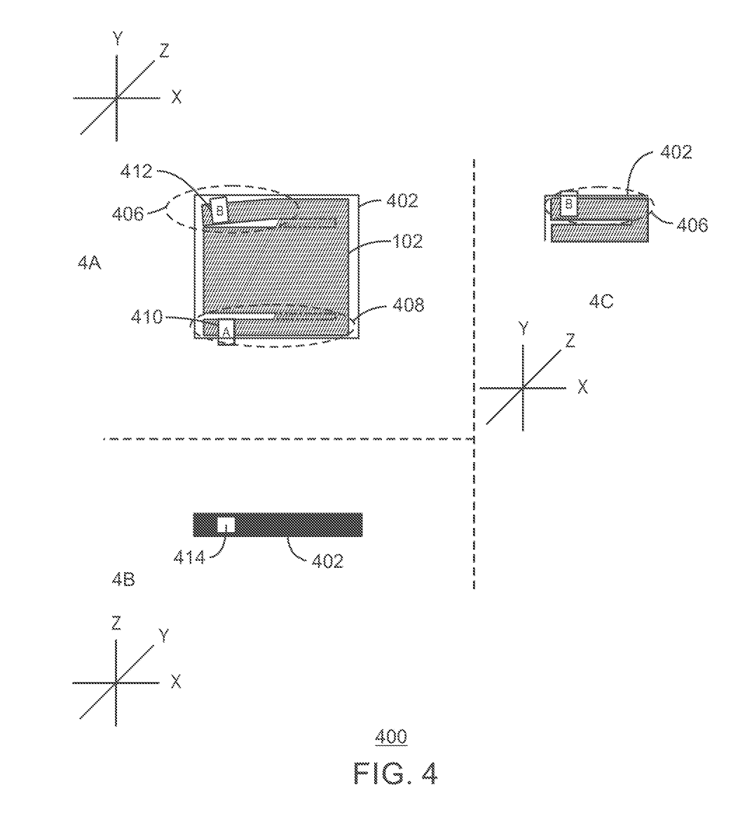

FIG. 4 is a block diagram of an example board, chassis, and a pliable region to aid a board with a component to insert into a chassis opening 400. Like numbered items are as described with respect to FIG. 1. In order to show various aspects of the example board, FIG. 4 includes 4A, 4B, and 4C to show the board 102 from a top view, a chassis 402 from a front view, and close up view of an assembly region of the board 102 and assembly chassis 402, respectively.

A board 102 can be designed to have compliancy in an X axis or Y axis rather than a Z axis for height alignment of components. In FIG. 4, assembly region A 404 and assembly region B 406 can correspond to assembly component A 408 and assembly component B 410. The assembly components can be as other components disclosed herein, and can also be used in assembly of the board 102 relative to other components, such as the assembly chassis 402. The assembly of the board 102 can refer to the use of board components to aid in alignment of components, the inserting of components, and also the inserting of the boa-rd into a chassis case without needing to remove or unmount components mounted to the board 102.

In FIG. 4A, the board 102 has cuts to create two assembly regions to aid in assembly of the board 102 into an assembly chassis 402. Assembly component A 408 and assembly component B 410 are mounted on the board 102 and specifically on their respective assembly regions. FIG. 4A shows assembly region B 406 flexing inwards towards the board 102 to allow a mounted assembly component B 410 to pass an assembly chassis 402 rim.

FIG. 4B shows a front-view of the assembly chassis 402 and an assembly port 412 that a component can fit into. The assembly port 412 can allow the component to be exposed to the exterior of the assembly chassis 402. The assembly port 412 can also be used by the assembly component to aid in alignment and anchoring of the board 102 to a position within the assembly chassis 402. In FIG. 4A, both the top and the lower sides have an assembly port 412 in the assembly chassis 402. One method of assembly of the board 102 into the assembly chassis is shown in FIGS. 4A and 4C. In FIG. 4A, assembly component A 408 can be inserted into an assembly port 412 in the assembly chassis 402. However, upon attempting to insert assembly component B 410 into the assembly port, the assembly component B 410 would be stopped by the rim of the assembly chassis 402. When the cuts are present forming assembly region B 406, then assembly region B 406 can typically be flexed inward while assembly component B 410 and the board can slide into position.

At FIG. 4C, assembly region B 406 is released when the assembly component B aligns with the assembly port 412 of the assembly chassis 402. As assembly region B 406 was formed with a cut, the deforming of the assembly region to a first point allowing insertion past the assembly chassis 402 rim and into the assembly port 412 can be followed by a restoring force to restore the board 102 to its shape. As seen in FIG. 4C, the cuts in the board are once again straight and the assembly region B 406 does not appear diverted towards the board.

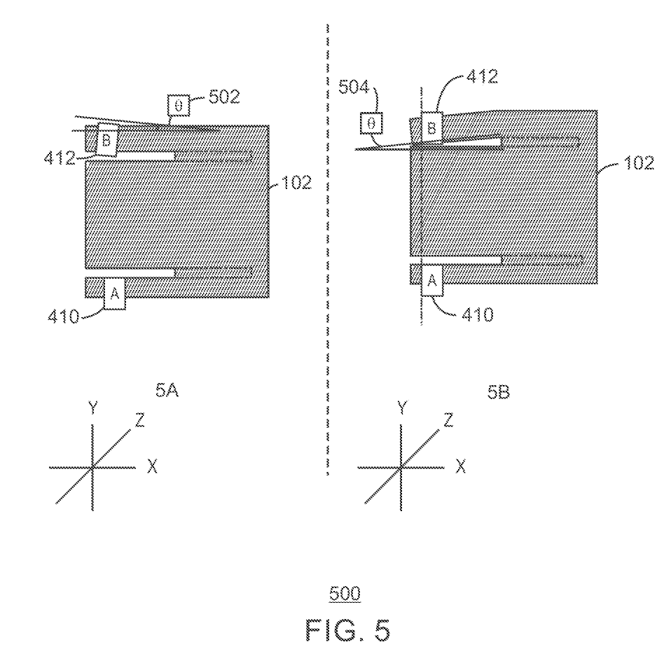

FIG. 5 is a block diagram of an example board and a pliable region to aid a component alignment on a board 500. Like numbered items are as described with respect to FIG. 1 and FIG. 4. In order to show various aspects of the example board. FIG. 5 includes 5A and 5B to show the board 102 from first view of a board 102 in neutral position and a board 102 in a deformed position, respectively.

As shown in FIG. 4, the deformation of the board 102 can allow placement of the board 102 in a chassis. In FIG. 5, a chassis is not shown, but there could be a designed container for the board 102 designed to be shaped in a non-square geometric layout. For example, the deformed shape of the board 102 in FIG. 5B could be a final, installed shape for a board 102 once inside electronics. If the assembly component A 408 and assembly component B 410 are mounted to the board 102 prior to installation and deformation, then a component could be skewed upon final board placement and flexing.

To account for this skewing, FIG. 5A shows the mounting of assembly component B 410 at a skew angle 502 equal to degrees matching a flex angle 504 in FIG. 5B. The mounting of assembly component B 410 at the skew angle 502 results in a final alignment of assembly component B 410 that can be coplanar with assembly component A 408 in a final position shown in FIG. 5B.

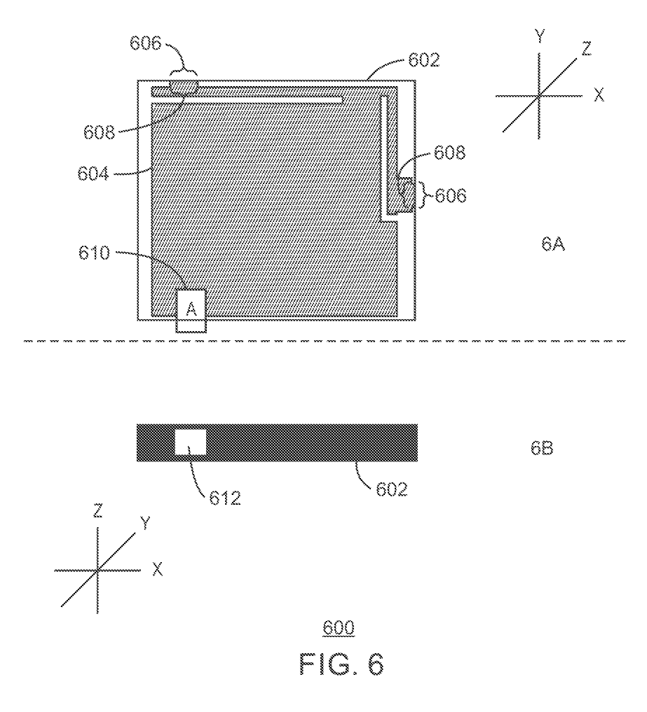

FIG. 6 is a block diagram of an example board, chassis, and pliable regions to aid in fixing the board to the chassis and inserting a connector of the board into a chassis opening 600. In order to show various aspects of the example board. FIG. 6 includes 6A and 68 to show the board from a top-down view of the board and chassis and a front view of the chassis, respectively.

As shown in FIG. 6, an interlocking chassis 602 can have a locking board 604 inserted and attached. An interlocking chassis 602 as used herein can be a chassis as described above, with the addition of slots, grooves, protrusions, indents, and similar physical alterations to allow a locking board 604 to attach to it through use of friction and without use of other affixing means such as screws, glue, nails, bonding, or other types of affixing means. As used herein, the locking board 604 can include regions and tabs that fit to the interlocking regions of the interlocking chassis 602.

The interlocking chassis 602 can include an interlocking region 606 such as a groove or an opening in the interlocking chassis 602. The locking board 604 can have a locking region 608 to fit within the interlocking region 606 and hold the locking board 604 in a designed position within the interlocking chassis 602. As shown in FIG. 6A, multiple interlocking regions 606 and locking regions 608 can exist with the same interlocking chassis 602 and interlocking board 604.

The use of a guiding component A 610 can increase the number of points of fixture between the interlocking chassis 602 and the locking board 604. The guiding component A 610 can be inserted into the receiving port 612 to expose the guiding component A 610 to an external edge of the interlocking chassis 602.

As seen in FIG. 6A, the locking regions 606 have cuts adjacent to them which form assembly beam regions. As discussed above, assembly beam regions can aid in deforming a board temporarily to aid in installation or inserting of a board into a chassis, among other benefits. As used in FIG. 6A, one possible order to insert and lock the locking board 604 into the interlocking chassis 602 could be first inserting the guiding component A 610 into the receiving port 612. Second the assembly beam regions could be flexed towards the board to temporarily decrease the size of the locking board 604. The locking board 604 could then be inserted into the interlocking chassis 602 to the point where the interlocking regions 606 were aligned to the locking regions 608 of the locking board 604. Upon alignment of these regions, the assembly beam regions could return to an unflexed state and thereby engage the locking region 608 with the interlocking region 606 of the chassis. As shown in FIG. 6, the assembly beam regions can be located on multiple edges of a board to add additional pliability in multiple directions.

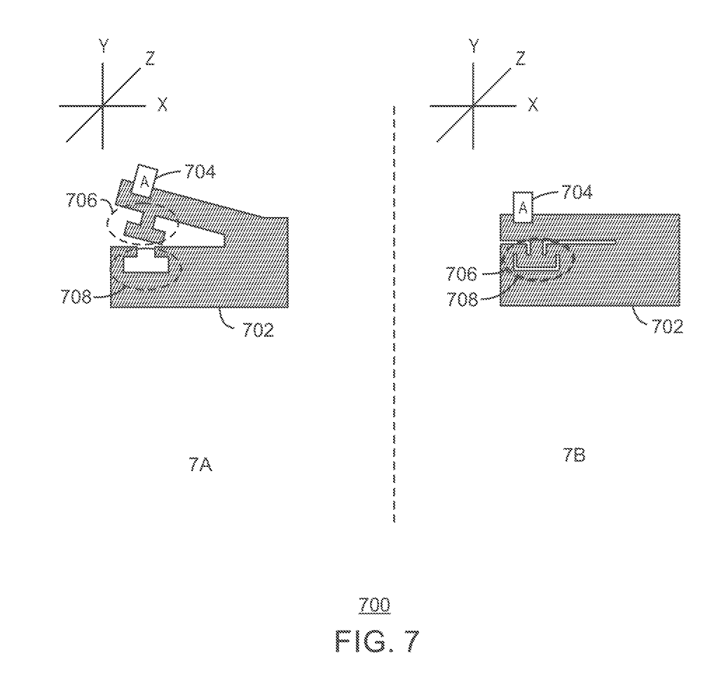

FIG. 7 is a block diagram of an example board with pliable regions to interlock 700. In order to show various aspects of the example board, FIG. 7 includes 7A and 7B to show the self-locking board 702 in a first relaxed position and a second self-locked position, respectively.

Similar to the locking and interlocking regions of FIG. 6, the self-locking board 702 can include a position-movable component A 704, a self-locking region 706, such as a geometry that is mirrored by a mating region, such as a self-interlocking region 708. In FIG. 7A, the self-locking board can be at a relaxed neutral state where no deformations have taken place. In FIG. 7B, the self-locking region 706 can be the geometry that is mirrored by the mating region of the board. As used herein, the mating region can include the self-interlocking region 708. In an example, the beam region can include a geometry that is mirrored by a mating region of the board with a shape that allows interlocking between the beam region of the board and the mating region of the board. The self-locking board 702 can attach to itself through use of friction and without use of other affixing means such as screws, glue, nails, bonding, or other types of affixing means. Further, although here the self-attaching board is shown in two-dimensions, three dimensional displacement of beam regions with self-locking regions are also contemplated.

Additionally, the capability shown in FIG. 7 can also be used in the reverse. For example, various geometries can be used to keep the board in a deflected position where FIG. 7B could show a “relaxed” or unflexed position, while FIG. 7A could show a final flexed position. Further, while FIG. 6 shows locking to a chassis and FIG. 7 shows self-locking to the board, these techniques can be interchanged or used in any combination for fixing a board to a chassis, to itself, to a second board, to a second chassis, or any other similar attaching possibility.

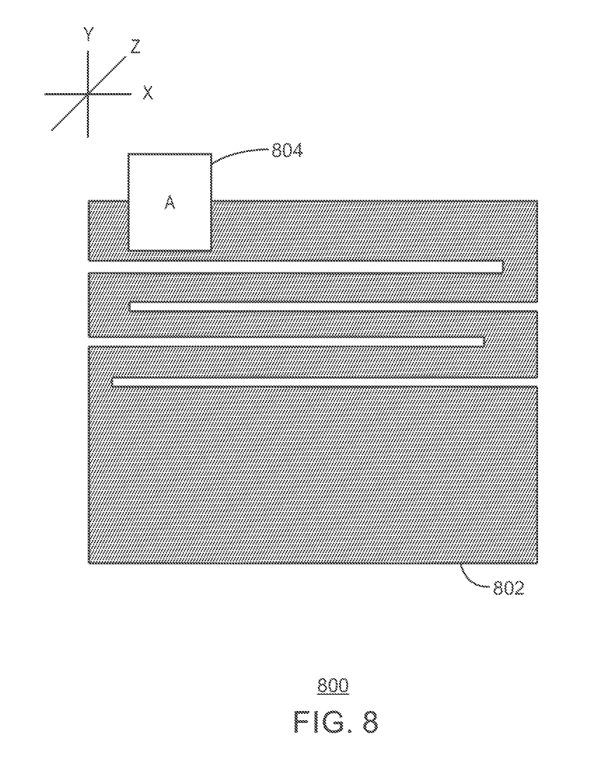

FIG. 8 is a block diagram of an example board with multiple pliable regions in proximity to each other to increase pliability of a target region 800. FIG. 8 shows a large-cut board 802 with a large-cut component A 804. The inclusion of a zig-zag pattern of cuts in the large-cut board 802 allow the large-cut board 802 to additively increase movement allowed on the beam region on which the large-cut component A 804 is mounted. The cuts shown can promote pliability in a Z axis, but also in an X axis and Y axis to the extent facilitated by the clearance of the cuts in those directions. Thus, depending on the designed shape for a final board product, X axis, Y axis, and Z axis compliancy can be achieved through combination of cut angles, directions, and geometries. Further, while mostly linear cuts are shown here, the cuts can be curved, and can have geometries that both flex and interlock to various regions in the X axis, Y axis, Z axis, or any combination thereof, in an example, a spiral cut could allow for pliability in every spatial direction.

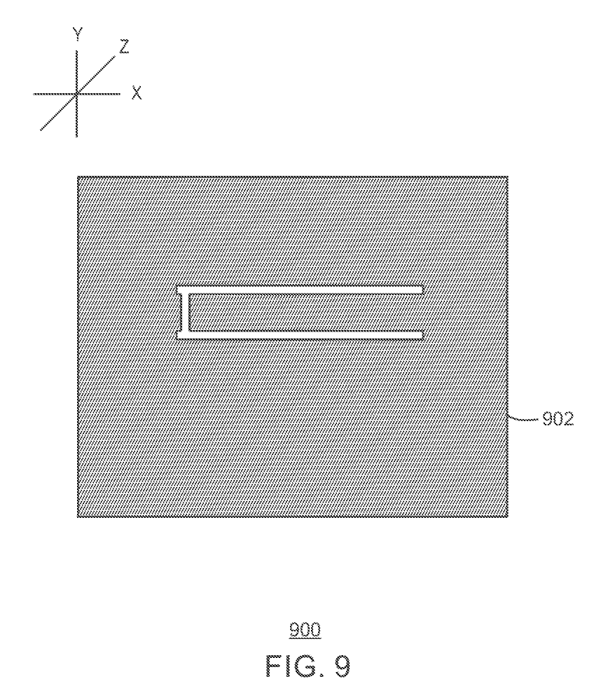

FIG. 9 is a block diagram of an example board with pliable regions internal to the board 900. The internal-cut board 902 shows that cuts may avoid the edge of a board and instead create a beam region for increased flexibility within the center of the internal-cut board 902. The internal-cut board 902 can be internal to the board by avoiding an X axis edge and a Y axis edge of a board. The increase flexibility can facilitate the positioning of components in an x dimension, a y dimension, and a z dimension with each dimension orthogonal to the others.

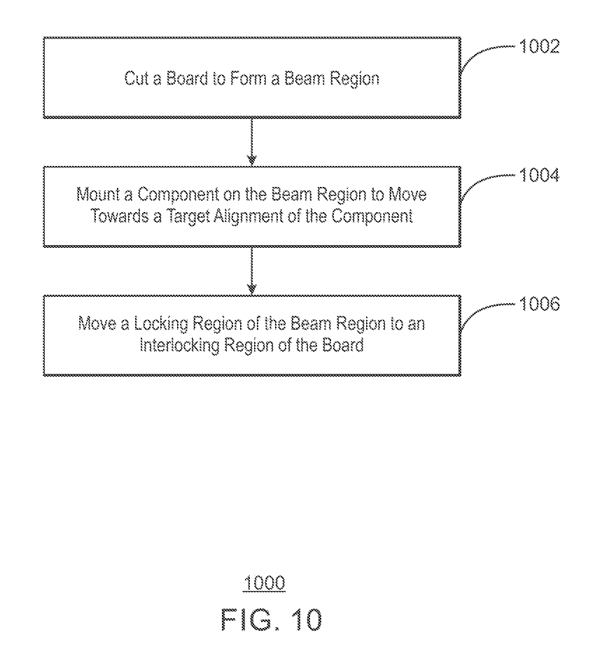

FIG. 10 is a process flow diagram of forming a rigid board with pliable regions. The example method begins at block 1002, where a content boundary can be identified. The method shown can be implemented to form the boards shown in FIGS. 1-9 and other similar variations.

At block 1002, a board can be cut to form a beam region and increase flexibility of the beam region relative to the board. In an example, the cut can be for a plurality of beam regions to increase pliability in an assembly region of the board. The board can be flexed along the assembly region to fit within a chassis.

At block 1004, a component can be mounted on the beam region to flexibly move relative to the board towards a target alignment of the component. In an example, the target alignment is a center-lire formed by a plane of an unflexed region of the board.

At block 1006, the locking region of the beam region can be moved to an interlocking region of the board. As discussed above, the interlocking region of the board can engage the locking region of the beam region through friction and without other adhesive means.

While the present techniques may be susceptible to various modifications and alternative forms, the techniques discussed above have been shown by way of example. It is to be understood that the technique is not intended to be limited to the particular examples disclosed herein. Indeed, the present techniques include all alternatives, modifications, and equivalents falling within the scope of the following claims.

What is claimed is:

1. A system for a rigid board With a pliable region, comprising:
a board comprising a cut to form a beam region of pliability in the board; and
a component to be mounted on the beam region, wherein the cut increases flexibility of the beam region relative to the board allowing movement of the component to a target alignment for the component.

2. The system of claim 1, wherein the beam region is to flex and secure the board to a chassis.

3. The system of claim 1, wherein the target alignment is a center-line formed by a line passing through the center-line along an exposed plane of a plurality of components mounted to the board.

4. The system of claim 1, comprising a second cut to form a second beam region placed to increase pliability in an assembly region that deforms along the second cut to fit within a chassis.

5. The system of claim 1, comprising:
a second component to be mounted on the board; and
a cooling element, wherein the second component is located on a second beam region of the board separate from the beam region of the first component, the beam region and the second beam region to be independently flexed to align the component and the second component for exposure to the cooling element.

6. The system of claim 1, wherein the cut is internal to the board by avoiding an X axis edge and a Y axis edge of a board.

7. The system of claim 1, wherein the cut in the board creates the beam region comprising a geometry that is mirrored by a mating region of the board to allow interlocking between the beam region of the board and the mating region of the board.

8. A system for a rigid board With a pliable region and a chassis, comprising:
a board comprising a cut to form a beam region of the board;
a component mounted on the beam region;
a chassis with an interlocking region; and
wherein the cut increases flexibility of the beam region relative to the board allowing movement of a beam region locking region to the interlocking region of the chassis.

9. The system of claim 8, wherein the target alignment is a center-line formed by a line passing through the center-line along an exposed plane of a plurality of components mounted to board; and
wherein the cut increases flexibility of the beam region relative to the board allowing movement of the component to a target alignment for the component.

10. The system of claim 8, wherein the cut is placed to increase pliability in an assembly region that deforms along the cut to fit within a chassis that the board could not fit into without deforming, the assembly region to revert to an undeformed state once fit within the chassis.

11. The system of claim 8, comprising:
a second component to be mounted on the board;
a cooling element; and
wherein the second component is located on a second beam region of the board separate from the beam region of the first component, the beam region and the second beam region to be independently flexed to align the component and the second component for exposure to the cooling element.

12. The system of claim 8, wherein the cut is internal to the board by avoiding an X axis edge and a Y axis edge of a board.

13. A method forming a rigid board with a pliable region, comprising:
cutting a board to form a beam region and increase flexibility of the beam region relative to the board;
mounting a component on the beam region to flexibly move relative to the board towards a target alignment of the component; and
moving a locking region of the beam region to an interlocking region of a chassis.

14. The method of claim 13, wherein the target alignment is a center-line formed by a line passing through the center-line along an exposed plane of a plurality of components mounted to the board.

15. The method of claim 13, comprising cutting a plurality of beam regions to increase pliability in an assembly region of the board.
